(19) United States
(12) Patent Application Publication
(10) Pub. No.: US 2022/0379403 A1
(43) Pub. Date: Dec. 1, 2022

(54) LASER PROCESSING APPARATUS

(71) Applicant: DISCO CORPORATION, Tokyo (JP)

(72) Inventor: Koji SHIONO, Tokyo (JP)

(21) Appl. No.: 17/663,744

(22) Filed: May 17, 2022

(30) Foreign Application Priority Data
May 31, 2021 (JP) 2021-091222

(51) Int. Cl. B23K 26/082; B23K 26/12; B23K 26/70; H01L 21/67

(52) U.S. Cl. CPC B23K 26/082; B23K 26/128; B23K 26/703; B23K 26/1224; H01L 21/67092; H01L 21/67115; B23K 2103/56

(57) ABSTRACT

A laser beam applying unit in a laser processing apparatus includes a laser oscillator for emitting a laser beam, a beam condenser for focusing the laser beam emitted from the laser oscillator and applying the focused laser beam to a workpiece held on a holding table, and a scanning unit that is disposed on an optical path of the laser beam between the laser oscillator and the beam condenser and that has scanning mirrors for scanning the laser beam and guiding the scanned laser beam toward the beam condenser. The scanning mirrors are housed in a chamber having a first window for allowing the laser beam emitted from the laser oscillator to pass therethrough to the scanning mirrors and a second window for allowing the laser beam scanned by the scanning mirrors to pass therethrough to the beam condenser.

### BACKGROUND OF THE INVENTION

### Field of the Invention

The present invention relates to a laser processing apparatus for processing a workpiece with a laser beam.

### Description of the Related Art

There have been proposed processing methods for dividing a semiconductor wafer where a functional layer including a low-k film or the like is layered on a face side thereof into chips. According to one of the proposed processing methods, after the layered functional layer has been removed by a laser beam applied thereto, a cutting blade cuts the semiconductor wafer to divide the semiconductor wafer into chips (see Japanese Patent Laid-open No. 2005-064231).

However, the proposed processing method is disadvantageous in that it suffers poor productivity as it needs to apply the laser beam several times to form sufficiently wide processed grooves in the semiconductor wafer in order to prevent melted substances such as debris produced by the applied laser beam from filling back processed grooves without being fully drained.

To solve the above problem, there has been developed a laser processing apparatus including a scanning optical system for scanning a laser beam, disposed between a laser oscillator and a beam condenser. In the laser processing apparatus, the laser beam is applied to a workpiece while scanning the workpiece, thereby efficiently processing the workpiece with the laser beam while preventing melted substances from filling back processed grooves (see Japanese Patent Laid-open No. 2016-068149).

### SUMMARY OF THE INVENTION

However, the above laser processing apparatus is problematic in that it makes it difficult for an operator of the laser processing apparatus to keep on working around the laser processing apparatus because of large noise produced when the scanning optical system operates at high speed.

It is therefore an object of the present invention to provide a laser processing apparatus having means for restraining noise produced by a scanning optical system when it operates at a high speed.

In accordance with an aspect of the present invention, there is provided a laser processing apparatus including a holding table for holding a workpiece thereon, a laser beam applying unit for focusing and applying a pulsed laser beam to the workpiece held on the holding table to process the workpiece, and a moving unit for moving the holding table and a focused spot of the pulsed laser beam relatively to each other. The laser beam applying unit includes a laser oscillator for emitting the pulsed laser beam, a beam condenser for focusing the pulsed laser beam emitted from the laser oscillator and applying the focused pulsed laser beam to the workpiece held on the holding table, and a scanning unit that is disposed on an optical path of the pulsed laser beam between the laser oscillator and the beam condenser, the scanning unit including a chamber and scanning mirrors housed in the chamber for scanning the pulsed laser beam and guiding the scanned laser beam toward the beam condenser. The chamber includes a first window for allowing the pulsed laser beam emitted from the laser oscillator to pass therethrough to the scanning mirrors, and a second window for allowing the pulsed laser beam scanned by the scanning mirrors to pass therethrough to the beam condenser.

Preferably, the laser processing apparatus further includes a suction source for evacuating the chamber, the chamber being held in fluid communication with the suction source.

Preferably, the laser processing apparatus further includes a cooling unit for cooling an inside of the chamber.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating a configuration example of a laser processing apparatus according to an embodiment of the present invention;

FIG. 2 is a schematic view illustrating a general configuration of a laser beam applying unit of the laser processing apparatus illustrated in FIG. 1; and

FIG. 3 is a schematic view illustrating at an enlarged scale a scanning unit and peripheral components of a laser beam applying unit according to a modification of the embodiment.

### DETAILED DESCRIPTION OF THE PREFERRED EMBODIMENTS

Preferred embodiments of the present invention will be described in detail hereinbelow with reference to the accompanying drawings. The present invention is not limited to the details of the embodiments described below. The components described below cover those which could easily be anticipated by those skilled in the art and those which are essentially identical to those described above. Further, the arrangements described below can be combined in appropriate manners. Various omissions, replacements, or changes of the arrangements may be made without departing from the scope of the present invention. In the description to be described below, those components that are identical to each other are denoted by identical reference signs, and will be omitted from description.

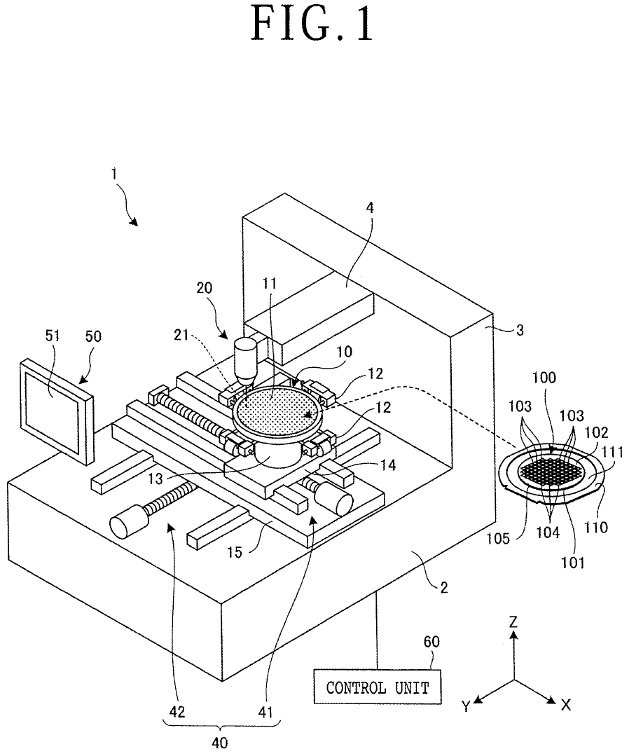

A laser processing apparatus 1 according to an embodiment of the present invention will be described in detail hereinbelow with reference to the drawings. FIG. 1 illustrates in perspective a configuration example of the laser processing apparatus 1 according to the present embodiment. In the description that follows, an X-axis direction refers to a direction in a horizontal plane, a Y-axis direction refers to a direction in the horizontal plane that is perpendicular to the X-axis direction, and a Z-axis direction refers to a direction that is perpendicular to the X-axis direction and the Y-axis direction. In the laser processing apparatus 1 according to the present embodiment, a processing feed direction is represented by the X-axis direction, and an indexing feed direction is represented by the Y-axis direction.

As illustrated in FIG. 1, the laser processing apparatus 1 according to the present embodiment includes a holding table 10, a laser beam applying unit 20, a moving unit 40, a display unit 50, and a control unit 60. The laser processing apparatus 1 is an apparatus for processing a workpiece 100 held on the holding table 10 with a pulsed laser beam 21 emitted from the laser beam applying unit 20 and applied to the workpiece 100. The laser processing apparatus 1 processes the workpiece 100 to form grooves in a face side of the workpiece 100 or to cut the workpiece 100 along projected dicing lines thereon, for example.

According to the present embodiment, the workpiece 100 is a wafer such as a semiconductor device wafer or an optical device wafer that is shaped as a circular plate and that has a substrate 101 made of silicon (Si), sapphire (Al₂O₃), gallium arsenide (GaAs), silicon carbide (SiC), lithium tantalite (LiTaO₃), or the like. The workpiece 100 is not limited to the shape and materials according to the embodiment. According to the present invention, the workpiece 100 may not be shaped as a circular plate.

The workpiece 100 has a grid of projected dicing lines 103 established on a face side 102 of the substrate 101 and a plurality of devices 104 formed in respective areas demarcated on the face side 102 by the projected dicing lines 103. The devices 104 are, for example, circuits such as integrated circuits (ICs) or large-scale-integration (LSI) circuits, or image sensors such as charge-coupled devices (CCDs) or complementary-metal-oxide-semiconductor (CMOS) image sensors. The workpiece 100 has a reverse side 105 to which there is affixed, for example, a circular adhesive tape 111 that is affixed at its outer circumferential edge portion to an annular frame 110 and that has a diameter larger than the diameter of the workpiece 100, the workpiece 100 being supported in the opening of the annular frame 110.

The holding table 10 has an upper surface acting as a holding surface 11 for holding the workpiece 100 thereon. The holding surface 11 is provided by a circular plate made of porous ceramic or the like. According to the present embodiment, the holding surface 11 is a flat surface lying parallel to horizontal directions, typically the X-axis direction and the Y-axis direction. The holding surface 11 is connected to a vacuum suction source, not illustrated, through a vacuum suction channel, not illustrated, for example. When the vacuum suction source is actuated, it generates and applies a suction force through the vacuum suction channel to the holding surface 11, holding the workpiece 100 placed on the holding surface 11 under suction. A plurality of clamps 12 are disposed around the holding table 10 for clamping the annular frame 110 that supports the workpiece 100 on the holding surface 11.

The holding table 10 is rotatable about an axis parallel to the Z-axis direction by a rotating unit 13. The rotating unit 13 and hence the holding table 10 are supported on an X-axis movable plate 14. The X-axis movable plate 14 with the rotating unit 13 and the holding table 10 supported thereon is movable in the X-axis direction by an X-axis moving unit 41 of the moving unit 40. The X-axis movable plate 14 is supported on a Y-axis movable plate 15. The Y-axis movable plate 15 with the X-axis movable plate 14 supported thereon is movable in the Y-axis direction by a Y-axis moving unit 42 of the moving unit 40 that is disposed on an apparatus base 2 of the laser processing apparatus 1. Therefore, the rotating unit 13 and the holding table 10 are movable in the X-axis direction by the X-axis moving unit 41 and also movable in the Y-axis direction by the Y-axis moving unit 42.

The laser beam applying unit 20 is a unit for emitting and applying the pulsed laser beam 21, which has a predetermined wavelength for processing the workpiece 100, to the workpiece 100 held on the holding table 10. According to the present embodiment, the laser beam applying unit 20 has a portion supported on a distal end of a support beam 4 whose proximal end is mounted on an upstanding wall 3 erected from the apparatus base 2. Configuration details of the laser beam applying unit 20 will be described later.

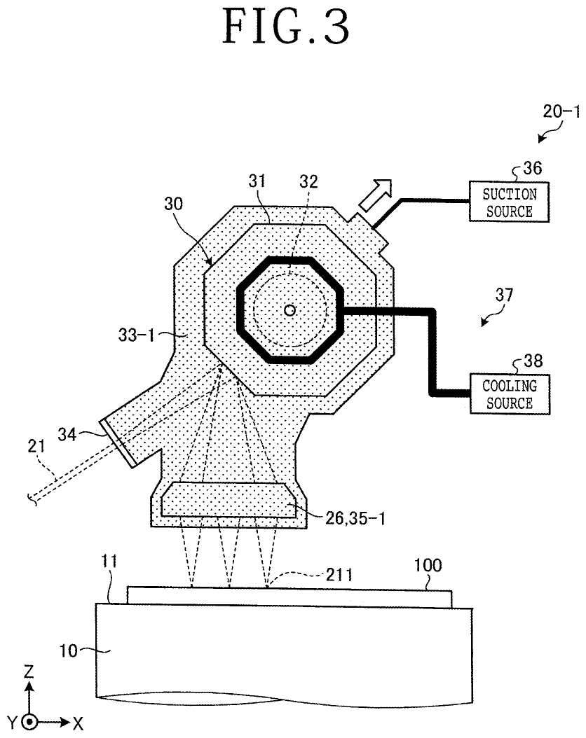

The moving unit 40 is a unit for moving a focused spot, e.g., a focused spot 211 illustrated in FIG. 3, of the laser beam 21 applied from the laser beam applying unit 20 and the holding table 10 relatively to each other. The moving unit 40 includes the X-axis moving unit 41 and the Y-axis moving unit 42, as described above.

The X-axis moving unit 41 is a unit for moving the focused spot, e.g., the focused spot 211 illustrated in FIG. 3, of the laser beam 21 applied from the laser beam applying unit 20 and the holding table 10 relatively to each other in the X-axis direction that represents the processing feed direction. According to the present embodiment, the X-axis moving unit 41 moves the holding table 10 in the X-axis direction. According to the present embodiment, the X-axis moving unit 41 is disposed over the apparatus base 2 of the laser processing apparatus 1. The X-axis movable plate 14 is movably supported on the X-axis moving unit 41 for movement in the X-axis direction.

The Y-axis moving unit 42 is a unit for moving the focused spot, e.g., the focused spot 211 illustrated in FIG. 3, of the laser beam 21 applied from the laser beam applying unit 20 and the holding table 10 relatively to each other in the Y-axis direction that represents the indexing feed direction. According to the present embodiment, the Y-axis moving unit 42 moves the holding table 10 in the Y-axis direction. According to the present embodiment, the Y-axis moving unit 42 is disposed on the apparatus base 2 of the laser processing apparatus 1. The Y-axis movable plate 15 is movably supported on the Y-axis moving unit 42 for movement in the Y-axis direction.

The X-axis moving unit 41 and the Y-axis moving unit 42 each include a known ball screw, a known stepping motor, and a pair of known guide rails, for example. The ball screw is rotatable about its central axis. The stepping motor is connected to one end of the ball screw for rotating the ball screw about its central axis. The guide rails of the X-axis moving unit 41 are fixedly mounted on the Y-axis movable plate 15, and the X-axis movable plate 14 is movably supported on the guide rails of the X-axis moving unit 41 for movement in the X-axis direction. The guide rails of the Y-axis moving unit 42 are fixedly mounted on the apparatus base 2, and the Y-axis movable plate 15 is movably supported on the guide rails of the Y-axis moving unit 42 for movement in the Y-axis direction.

The display unit 50 is a display device such as a liquid crystal display device having a display surface 51. The display unit 50 displays on the display surface 51 a screen for setting processing conditions, the state of the workpiece 100 that is represented by an image captured by an image capturing unit, not illustrated, and the state of a processing operation in progress on the workpiece 100, for example. In a case where the display surface 51 of the display unit 50 includes a touch panel, the display unit 50 may include an input device. The input device can accept various operating actions made by an operator of the laser processing apparatus 1 to register processing contents information, for example. The input device may be an external input device such as a keyboard. Items of information and images displayed on the display surface 51 can be switched over by operating actions entered into the input device by the operator, for example. The display unit 50 may include a signaling device. The signaling device emits at least one of sound and light to give predetermined signaling information to the operator. The laser processing apparatus 1 may alternatively have an external signaling device such as a speaker or a light emitting device.

The control unit 60 controls the various components referred to above of the laser processing apparatus 1 to enable the laser processing apparatus 1 to perform a processing operation for processing the workpiece 100. The control unit 60 is a computer including a processing device as processing means, a storage device as storing means, and an input/output interface as communicating means. The processing device includes a microprocessor such as a central processing unit (CPU). The storage device includes a memory such as a read only memory (ROM) or a random access memory (RAM). The processing device performs various processing operations based on predetermined programs stored in the storage device. The processing device outputs various control signals via the input/output interface to the components of the laser processing apparatus 1 according to results of the processing operations, thereby controlling the laser processing apparatus 1.

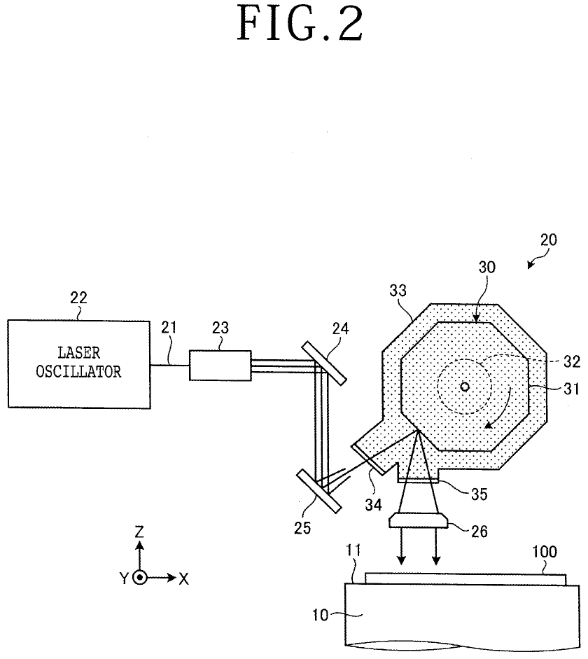

Configuration details of the laser beam applying unit 20 will be described below. FIG. 2 schematically illustrates a general configuration of the laser beam applying unit 20 of the laser processing apparatus 1 illustrated in FIG. 1. As illustrated in FIG. 2, the laser beam applying unit 20 includes a laser oscillator 22, an acousto-optic deflector (AOD) 23, mirrors 24 and 25, a beam condenser 26, a scanning unit 30 as a scanning optical system, and a chamber 33.

The laser oscillator 22 emits the pulsed laser beam 21 having the predetermined wavelength for processing the workpiece 100. According to the present embodiment, the wavelength of the laser beam 21 emitted by the laser oscillator 22 is absorbable by the workpiece 100.

The acousto-optic deflector 23 operates in response to a predetermined high acoustic frequency applied thereto to deflect the optical path of the laser beam 21 emitted from the laser oscillator 22 in a predetermined direction, i.e., the Y-axis direction according to the present embodiment, to scan the workpiece 100 with the deflected laser beam 21. The acousto-optic deflector 23 adjusts the angle through which to deflect the optical path of the laser beam 21, depending on the acoustic frequency applied thereto. The laser beam 21 thus deflected scans the workpiece 100 in the Y-axis direction.

According to the present embodiment, the mirrors 24 and 25 are disposed on the optical path of the laser beam 21 between the acoustic-optic deflector 23 and the scanning unit 30. The mirrors 24 and 25 propagate the laser beam 21 emitted from the laser oscillator 22 and deflected by the acoustic-optic deflector 23 to the scanning unit 30.

The beam condenser 26 receives the laser beam 21 scanned by the scanning unit 30. The beam condenser 26 focuses the laser beam 21 from the scanning unit 30 and applies the focused laser beam 21 to the workpiece 100 held on the holding table 10. According to the present embodiment, the beam condenser 26 is an fθ lens. Specifically, the beam condenser 26 is a lens assembly including a plurality of lenses that function as an fθ lens.

The scanning unit 30 is disposed on the optical path of the laser beam 21 between the laser oscillator 22 and the beam condenser 26. The scanning unit 30 scans the laser beam 21 and guides the scanned laser beam 21 to the beam condenser 26. According to the present embodiment, the scanning unit 30 includes a polygon scanner. According to the present invention, however, the scanning unit 30 may include a resonant scanner. Specifically, the scanning unit 30 includes a plurality of scanning mirrors 31 and a scanning motor 32.

The scanning mirrors 31 are rotatable or oscillatable about an axis parallel to the indexing feed direction that is represented by the Y-axis direction. According to the present embodiment, the scanning mirrors 31 are attached to respective facets of a polygonal prism, i.e., an octagonal prism according to the present embodiment, that is rotatable about the axis. The polygonal prism has a shaft extending along the axis and held by a mirror holder, not illustrated. The beam condenser 26 has a front focal point positioned on one of the scanning mirrors 31, to which the laser beam 21 is applied from the mirror 25, in the scanning unit 30. The scanning motor 32 outputs rotational power for rotating or oscillating the scanning mirrors 31 about the axis.

According to the present embodiment, the laser beam 21 deflected by the acoustic-optic deflector 23 is applied via the mirrors 24 and 25 to the scanning unit 30. The scanning unit 30 reflects, by the scanning mirrors 31, the applied laser beam 21 toward the beam condenser 26 in a direction parallel to an XZ plane, and scans the laser beam 21 in the X-axis direction by rotating the scanning mirrors 31 about the axis parallel to the Y-axis direction.

The chamber 33 houses the scanning mirrors 31 therein. The chamber 33 has a first window 34 and a second window 35. The first window 34 and the second window 35 are disposed on a wall of the chamber 33 that separates the inside of the chamber 33 and the surrounding environment from each other at respective positions where the laser beam 21 goes into and out of the chamber 33. The first window 34 allows the laser beam 21 from the laser oscillator 22 to pass therethrough toward the scanning mirrors 31 in the chamber 33. The second window 35 allows the laser beam 21 scanned by the scanning mirrors 31 to pass therethrough toward the beam condenser 26. While the scanning unit 30 is in operation, the scanning mirrors 31 are rotated at a high speed and produce noise. However, since the scanning mirrors 31 are housed in the chamber 33, the noise produced by the scanning mirrors 31 is restrained outside of the laser beam applying unit 20.

### Modification:

A laser beam applying unit 20-1 according to a modification of the embodiment will be described below with reference to FIG. 3. Those components of the laser beam applying unit 20-1 that are identical to those of the laser beam applying unit 20 according to the above embodiment are denoted by identical reference signs and will be omitted from description. FIG. 3 schematically illustrates at an enlarged scale the scanning unit 30 and peripheral components of the laser beam applying unit 20-1 according to the present modification.

The laser beam applying unit 20-1 according to the modification has a chamber 33-1 instead of the chamber 33 of the laser beam applying unit 20 according to the embodiment. The chamber 33-1 houses the scanning mirrors 31 therein as with the chamber 33 according to the embodiment. The chamber 33-1 does not house the scanning motor 32 of the scanning unit 30 therein.

The chamber 33-1 has a first window 34 and a second window 35-1. The first window 34 and the second window 35-1 are disposed on the wall of the chamber 33-1 that separates the inside of the chamber 33-1 and the surrounding environment from each other at respective positions where the laser beam 21 goes into and out of the chamber 33-1. The first window 34 allows the laser beam 21 from the laser oscillator 22 to pass therethrough toward the scanning mirrors 31 in the chamber 33-1.

According to the modification, the second window 35-1 is provided as the beam condenser 26 that focuses the laser beam 21 scanned by the scanning mirrors 31 and that applies the focused laser beam 21 to the workpiece 100 held on the holding table 10. The second window 35-1 is fixedly provided in the chamber 33-1. The beam condenser 26 is disposed on the wall of the chamber 33-1 that separates the inside of the chamber 33-1 and the surrounding environment from each other, as the second window 35-1 through which the laser beam 21 passes. The chamber 33-1 according to the modification thus functions as a lens holder for the beam condenser 26. Therefore, the beam condenser 26 is unitized at a fixed distance from and a fixed position with respect to the scanning mirrors 31.

The chamber 33-1 according to the modification is held in fluid communication with a suction source 36. The suction source 36 is capable of evacuating the chamber 33-1 to approximately 1/10 of the atmospheric pressure, for example. When the chamber 33-1 is evacuated at the time the laser beam applying unit 20-1 is in operation, the air resistance to the scanning mirrors 31 as they rotate is reduced, thereby restraining noise produced by the rotating scanning mirrors 31. Moreover, when the chamber 33-1 is evacuated, it is effective to reduce the leakage of noise produced by the scanning mirrors 31 in the chamber 33-1.

The chamber 33-1 according to the modification incorporates therein a cooling unit 37 that can cool the inside of the chamber 33-1. The cooling unit 37 includes a cooling structure disposed in sandwiching relation to the scanning mirrors 31 along the axis thereof, for example. The cooling unit 37 is connected to a cooling source 38 and cools the inside of the chamber 33-1 with cooling water supplied from the cooling source 38, for example.

The laser processing apparatuses according to the embodiment and the modification are capable of restraining noise produced by the scanning mirrors 31 while they are rotated at a high speed because the scanning mirrors 31 are housed in the chambers 33 and 33-1.

Furthermore, the laser processing apparatus according to the modification is able to restrain noise produced by the scanning mirrors 31 while they are rotated at a high speed and also to reduce the leakage of noise by evacuating the chamber 33-1. The laser processing apparatus according to the modification is also able to reduce a thermal load due to the heat generated by the scanning mirrors 31 rotating at a high speed, by cooling the inside of the chamber 33-1, thereby preventing a processing failure such as a shift of the position where the workpiece 100 is processed by the laser beam 21.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A laser processing apparatus comprising:
a holding table for holding a workpiece thereon;
a laser beam applying unit for focusing and applying a pulsed laser beam to the workpiece held on the holding table, to process the workpiece; and
a moving unit for moving the holding table and a focused spot of the pulsed laser beam relatively to each other,
wherein the laser beam applying unit includes
a laser oscillator for emitting the pulsed laser beam,
a beam condenser for focusing the pulsed laser beam emitted from the laser oscillator and applying the focused pulsed laser beam to the workpiece held on the holding table, and
a scanning unit that is disposed on an optical path of the pulsed laser beam between the laser oscillator and the beam condenser, the scanning unit including a chamber and scanning mirrors housed in the chamber for scanning the pulsed laser beam and guiding the scanned laser beam toward the beam condenser, and
wherein the chamber includes
a first window for allowing the pulsed laser beam emitted from the laser oscillator to pass therethrough to the scanning mirrors, and
a second window for allowing the pulsed laser beam scanned by the scanning mirrors to pass therethrough to the beam condenser.

2. The laser processing apparatus according to claim 1, further comprising:
a suction source for evacuating the chamber, the chamber being held in fluid communication with the suction source.

3. The laser processing apparatus according to claim 1, further comprising:
a cooling unit for cooling an inside of the chamber.
